(19) United States
(12) Patent Application Publication
(10) Pub. No.: US 2009/0039428 A1
(43) Pub. Date: Feb. 12, 2009

(54) FABRICATING METHOD FOR SILICON ON INSULATOR AND STRUCTURE THEREOF

(75) Inventors: Hsiao-Che Wu, Chung-Li City (TW); Ming-Yen Li, Fongshan City (TW); Wen-Li Tsai, Renwu Township (TW)

Correspondence Address: Muncy, Geissler, Olds & Lowe, PLLC, P.O. BOX 1364, FAIRFAX, VA, 22038-1364, US

(73) Assignee: ProMOS Technologies Inc.

(21) Appl. No.: 12/053,679

(22) Filed: Mar. 24, 2008

(30) Foreign Application Priority Data
Aug. 8, 2007 (TW) 96129281

(51) Int. Cl. H01L 29/00; H01L 21/20

(52) U.S. Cl. 257/347; 438/429; 257/E29.001; 257/E21.09

(57) ABSTRACT

A fabricating method for silicon on insulator is disclosed, and the fabricating method includes stripping the oxide and the nitride on the bottom surface of each of the trenches, forming a porous silicon on portions of the substrate by an anodizing process, spin coating a dielectric material to fill up the trenches and performing a thermal process to convert the porous silicon to an insulating layer.

### RELATED APPLICATIONS

This application claims priority to Taiwan Application Serial Number 96129281, filed Aug. 8, 2007, which is herein incorporated by reference.

### BACKGROUND

1. Field of Invention

The present invention relates to a fabricating method for silicon on insulator and structure thereof, and more particularly to a fabricating method for silicon on insulator and structure thereof with less cost.

2. Description of Related Art

In semiconductor manufacturing, silicon on insulator (SOI) is a typical technique for transistors electronically isolating, and this technique mainly includes two types, bonded silicon on insulator and high-current oxygen ion implantation.

With respect to bonded silicon on insulator, this method involves two wafers wherein silicon dioxide is grown on both of them, and the micro-porous layer is formed in one of the wafer through hydrogen implantation. Then, the two wafers are pressed face to face at a high temperature to bond them together with silicon dioxide diffusion, and the micro-porous layer is cut to divide the wafers.

Regarding high-current oxygen ion implantation, the oxygen rich junction is formed under the silicon surface through high-current oxygen ion implantation, and the buried oxide is formed by an annealing process. However, both of these methods involve high cost and low throughput.

### SUMMARY

It is therefore an aspect to provide a fabricating method for silicon on insulator to reduce cost.

Accordingly, a fabricating method for silicon on insulator of the embodiment includes forming a plurality of trenches on the substrate, forming an oxide on the inner surface of the trenches, forming nitride on the oxide, stripping the oxide and the nitride on the bottom surface of the trenches, forming a porous silicon on portion of the substrate by an anodizing process, spin coating a dielectric material to fill up the trenches and performing a thermal process to convert the porous silicon to an insulating layer.

As a result, the fabricating method for silicon on insulator can substitute for the conventional bonded silicon on insulator and high-current oxygen ion implantation to reduce cost and raise the throughput.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a sectional view of the SOI structure of the embodiment in accordance with the present invention; and

FIG. 2a to FIG. 2f are the sectional views of the SOI structure of the embodiment in different processes.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

While the specification concludes with claims defining the features of the invention that are regarded as novel, it is believed that the invention will be better understood from a consideration of the following description in conjunction with the figures, in which like reference numerals are carried forward.

Refer to FIG. 1, which illustrates a sectional view of the SOI structure of the embodiment in accordance with the present invention.

The silicon on insulator (SOI) structure of the embodiment includes a base 100, a trench 200, an oxide 300, a nitride 400 and a second dielectric material 510. The base 100 has a substrate 110, a plurality of protrusions 120, a pad oxide 130, a pad nitride 140 and an insulating layer 151. The pad oxide 130 is formed on the protrusions 120, and the pad nitride 140 is formed on the pad oxide 130 such that the pad oxide 130 is disposed between the pad nitride 140 and each of the protrusions 120. The trench 200 is formed between each adjacent pair of the protrusions 120. The oxide 300 is grown on the side surface of the trench 200, and is connected with the pad oxide 130 and the insulating layer 151 to cover each of the protrusions 120. The nitride 400 is coated on the oxide 300, and is connected with the pad nitride 140. The second dielectric material 510 is filled with the trench 200 to form the shallow trench isolation (STI) structure.

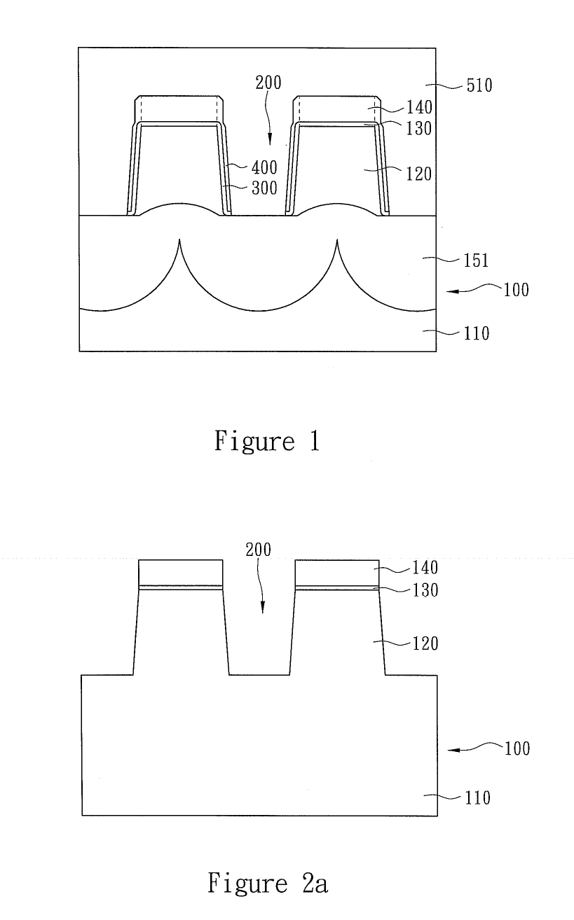

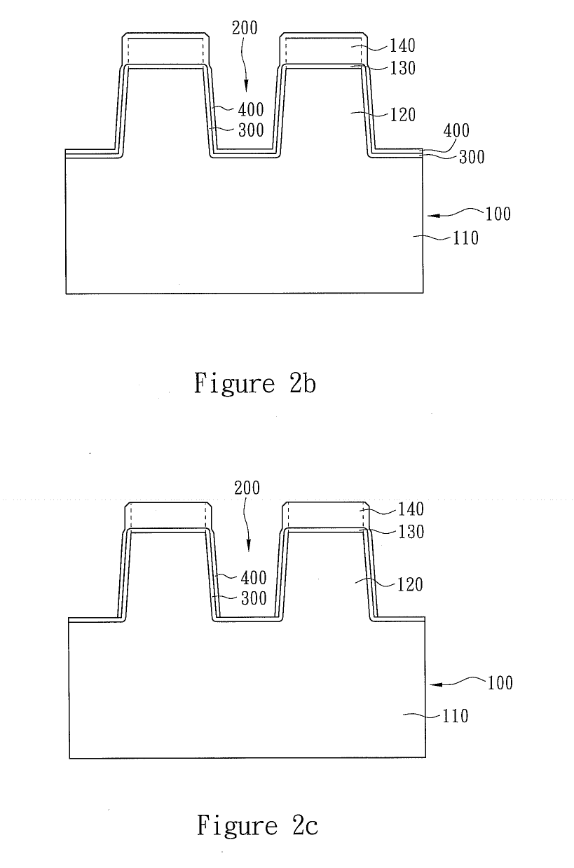

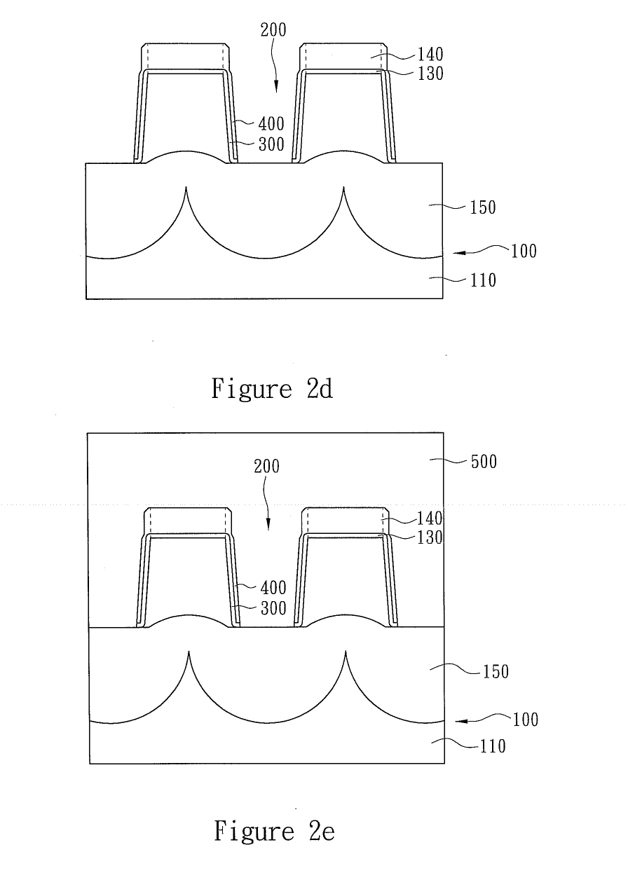

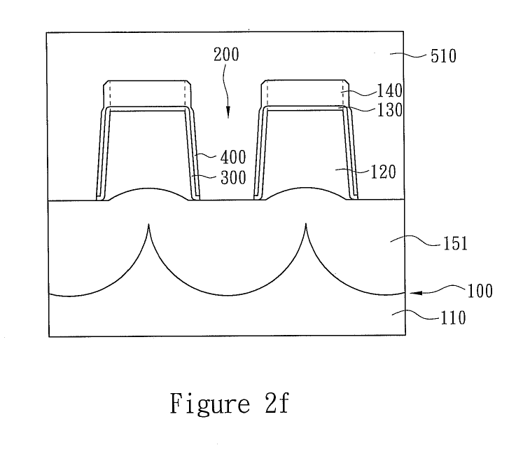

Refer to FIG. 2a to FIG. 2f, which illustrate the sectional view of the SOI structure of the embodiment in different processes.

Refer to FIG. 2a and FIG. 2b. The oxide 300 is grown on the inner surface of the trench 200 through thermal oxidation to cover the side surface and the bottom surface of the trench 200. The oxide 300 is connected with the pad oxide 130. The nitride 400 is coated on the oxide 300 through deposition, and is connected with the pad nitride 140.

Refer to FIG. 2c. Stripping the nitride 400 disposed on the bottom surface of the trench 200 through anisotropic etching process. Therefore, the remaining nitride 400 disposed on the side surface forms the nitride sidewall. Refer to FIG. 2d. Stripping the oxide 300 disposed on the bottom surface of the trench 200 to form an insulating spacer at each trench sidewall (the oxide 300 and the nitride 400). Moreover, forming porous silicon 150 on portions of the substrate 110 by anodizing process. Refer to FIG. 2e. Spin coating a first dielectric material 500 to fill up the trench 200 wherein the first dielectric material 500 covers the porous silicon 150.

Refer to FIG. 2f. Performing an annealing process with oxygen-containing atmosphere such that the oxygen passes through the first dielectric material 500 to combine with the porous silicon 150 to convert the porous silicon 150 to the insulating layer 151 (silicon dioxide). In addition, the first dielectric material 500 (shown as FIG. 2e) is converted to the second dielectric material 510.

As embodied and broadly described herein, the porous silicon 150 of the SOI structure is formed on portions of the substrate 110 by an anodizing process, and spin coating the first dielectric material 500 to fill up the trench 200. The porous silicon 150 is then converted to the insulating layer 151, made of silicon dioxide, by performing an annealing process. Therefore, the fabricating method for silicon on insulator and the structure thereof can reduce the cost and raise the throughput.

Although the present invention has been described in considerable detail with reference to certain preferred embodiments thereof, other embodiments are possible. Therefore, the spirit and scope of the appended claims should not be limited to the description of the preferred embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fabricating method for silicon on insulator, comprising:
forming a plurality of trenches on a substrate;
forming an insulating spacer at each trench sidewall;
forming a porous silicon on each of a plurality of portions of the substrate in the trenches by an anodizing process;
spin coating a dielectric material to fill up the trenches wherein the dielectric material covers the porous silicon; and
performing a thermal process to convert the porous silicon to an insulating layer.

2. The fabricating method for silicon on insulator of claim 1, wherein the forming insulating spacer step comprises:
forming an oxide on a side surface and a bottom surface of each of the trenches;
forming a nitride on the oxide; and
stripping the oxide and the nitride on the bottom surface of each of the trenches.

3. The fabricating method for silicon on insulator of claim 2, wherein the stripping step is an anisotropic etching process.

4. The fabricating method for silicon on insulator of claim 1, wherein the thermal process is an annealing process with oxygen-containing atmosphere.

5. A structure of silicon on insulator, comprising:
a base comprising a substrate, multiple protrusions and an insulating layer wherein the insulating layer is disposed between the substrate and the protrusions;
a plurality of trenches formed respectively between the protrusions;
an oxide grown on a side surface of each of the trenches;
a nitride coated on the oxide; and
a dielectric material filled with the trenches.

6. The structure of silicon on insulator of claim 5, wherein the base comprises a pad oxide formed on each of the protrusions and a pad nitride formed on the pad oxide.

7. The structure of silicon on insulator of claim 5, wherein the substrate is a silicon substrate.

8. The structure of silicon on insulator of claim 5, wherein the insulating layer is a silicon dioxide layer.

9. The structure of silicon on insulator of claim 5, wherein the nitride is a silicon nitride layer.
